(19) United States
(12) Patent Application Publication
(10) Pub. No.: US 2024/0267015 A1
(43) Pub. Date: Aug. 8, 2024

(54) LOAD-MODULATED BALANCED AMPLIFIER (LMBA) BASED ON VARIABLE CROSS-COUPLED PAIR (XCP)

(71) Applicant: CHENGDU FLUXWORKS TECHNOLOGY CO., LTD, Chengdu (CN)

(72) Inventors: Kai YI, Chengdu (CN); Kai KANG, Chengdu (CN); Chenxi ZHAO, Chengdu (CN); Huihua LIU, Chengdu (CN)

(73) Assignee: CHENGDU FLUXWORKS TECHNOLOGY CO., LTD, Chengdu (CN)

(21) Appl. No.: 18/566,099

(22) PCT Filed: May 26, 2023
(86) PCT No.: PCT/CN2023/096529

§ 371 Date: Dec. 1, 2023

(30) Foreign Application Priority Data
Sep. 16, 2022 (CN) 202211131218.1

(51) Int. Cl. H03G 3/00; H03F 1/08; H03F 3/45

(52) U.S. Cl. CPC H03G 3/007; H03F 1/086; H03F 3/45264; H03F 2200/451

(57) ABSTRACT

A load-modulated balanced amplifier (LMBA) based on a variable cross-coupled pair (XCP) is provided. The LMBA includes an adaptive bias (ADB) circuit, a first balance terminal amplifier module, a second balance terminal amplifier module, a control terminal amplifier module, a first driver amplifier module, a second driver amplifier module, a third driver amplifier module, a variable XCP, a resistor R5, a resistor R6, a 90-degree differential coupler Q1, a 90-degree differential coupler Q2, and a 90-degree differential coupler Q3.

### CROSS REFERENCE TO THE RELATED APPLICATIONS

This application is the national phase entry of International Application No. PCT/CN2023/096529, filed on May 26, 2023, which is based upon and claims priority to Chinese Patent Application No. 202211131218.1, filed on Nov. 16, 2022, the entire contents of which are incorporated herein by reference.

### TECHNICAL FIELD

The present disclosure relates to the technical field of wireless communications, and in particular to a load-modulated balanced amplifier (LMBA) based on a variable cross-coupled pair (XCP).

### BACKGROUND

With the emergence of fifth-generation (5G) wireless communication systems, increasingly high requirements are imposed on the data rate. Due to scarce spectrum resources, low-latency and large-capacity wireless connections require advanced modulation schemes to improve the utilization rate of the spectrum resources. However, these complicated modulated wireless waves have a high peak-to-average power ratio (PAPR) that greatly reduces efficiency of a conventional power amplifier. In order to improve the efficiency of the power amplifier for amplifying signals with a high PAPR, a load-modulated balanced amplifier (LMBA) has been proposed in recent years. The LMBA includes a balance terminal amplifier and a control terminal amplifier. Load modulation is realized by changing the ratio of the output power of a control terminal amplifier to the output power of a balance terminal amplifier. The balance terminal amplifier works in a class-C mode, while the control terminal amplifier works in a class-AB mode.

The class-AB amplifier and the class-C amplifier are greatly different in gain in the millimeter-wave frequency band. The class-C amplifier has a very low gain. After the balance terminal amplifier is turned on, the overall gain of the amplifier is reduced dramatically with an increase of input power, and thus the linearity of the amplifier is seriously affected. This restricts application of the LMBA in the millimeter-wave frequency band.

### SUMMARY

In view of shortages in the prior art, the present disclosure provides an LMBA based on a variable XCP, to solve the problem that a class-AB amplifier and a class-C amplifier are greatly different in gain in a millimeter wave band to restrict an application of the LMBA in the millimeter-wave frequency band.

To achieve the above objective, the present disclosure adopts the following technical solutions:

An LMBA based on a variable XCP includes an adaptive bias (ADB) circuit, a first balance terminal amplifier module, a second balance terminal amplifier module, a control terminal amplifier module, a first driver amplifier module, a second driver amplifier module, a third driver amplifier module, a variable XCP, a resistor R5, a resistor R6, a 90-degree differential coupler Q1, a 90-degree differential coupler Q2, and a 90-degree differential coupler Q3, where an input terminal of the ADB circuit and a third input terminal of the 90-degree differential coupler Q1 each serve as an input terminal of an amplifier; one terminal of an isolated terminal of the 90-degree differential coupler Q1 is connected to the other terminal of the isolated terminal of the 90-degree differential coupler Q1 through the resistor R5; a pass-through terminal of the 90-degree differential coupler Q1 includes one terminal connected to a first input terminal of the 90-degree differential coupler Q2, and the other terminal connected to a second input terminal of the 90-degree differential coupler Q2; one terminal of an isolated terminal of the 90-degree differential coupler Q2 is connected to the other terminal of the isolated terminal of the 90-degree differential coupler Q2 through the resistor R6; a third output terminal of the 90-degree differential coupler Q1 is connected to an input terminal of the third driver amplifier module; an output terminal of the third driver amplifier module is connected to an input terminal of the control terminal amplifier module; a coupling terminal of the 90-degree differential coupler Q₂ includes one terminal connected to a first input terminal of the first driver amplifier module, and the other terminal connected to a second input terminal of the first driver amplifier module; a pass-through terminal of the 90-degree differential coupler Q₂ includes one terminal connected to a first input terminal of the second driver amplifier module, and the other terminal connected to a second input terminal of the second driver amplifier module; an output terminal of the first driver amplifier module is connected to an input terminal of the first balance terminal amplifier module; an output terminal of the second driver amplifier module is connected to an input terminal of the second balance terminal amplifier module; a first output terminal and a second output terminal of the first balance terminal amplifier module are respectively connected to one terminal of a pass-through terminal of the 90-degree differential coupler Q₃ and the other terminal of the pass-through terminal of the 90-degree differential coupler Q₃; the second balance terminal amplifier module includes a first output terminal connected to one terminal of a coupling terminal of the 90-degree differential coupler Q₃, and a second output terminal connected to the other terminal of the coupling terminal of the 90-degree differential coupler Q₃; an output terminal of the control terminal amplifier module is connected to an isolated terminal of the 90-degree differential coupler Q₃; and an output terminal of the 90-degree differential coupler Q₃ serves as an output terminal of the millimeter-wave LMBA based on the variable XCP.

Further, the ADB circuit includes a transistor M₄ₙ a resistor R_{LP}, a capacitor C_{LP}, a transistor M₄ₙ, a transistor M₅ₙ, a transistor M₆ₙ, a transistor M₄ₚ, a transistor M₅ₚ, a transistor M₆ₚ, a resistor R1, a resistor R2, a capacitor C1, a capacitor C2, a capacitor C3 and a capacitor C4; and the capacitor C1 includes one terminal serving as the input terminal of the ADB circuit, and the other terminal connected to one terminal of the resistor R1 and a base of the transistor M₄; the other terminal of the resistor R1 is connected to a detection voltage; an emitter of the transistor M₄ is grounded; a collector of the transistor M₄ is connected to one terminal of the resistor R_{LP}, one terminal of the capacitor C_{LP}, a base of the transistor M₄ₙ, a base of the transistor M₅ₙ, a base of the transistor M₆ₙ, a base of the transistor M₄ₚ, a base of the transistor M₅ₚ, and a base of the transistor M₆ₚ; the other terminal of the resistor R_{LP} is connected to a 1V power supply and the other terminal of the capacitor C_{LP}; a collector of the transistor M₄ₚ is connected to a bias voltage V_{cnt1}; a collector of the transistor M₅ₚ is connected to the bias voltage V_{cnt1}; a collector of the transistor M₆ₚ is connected to a bias voltage V_{cnt2}; an emitter of the transistor M₄ₚ is connected to one terminal of the capacitor C4, one terminal of the resistor R2 and a collector of the transistor M₄ₙ; the other terminal of the capacitor C4 is grounded; an emitter of the transistor M₄ₙ is grounded; an emitter of the transistor M₅ₚ is connected to one terminal of the capacitor C3, one terminal of the resistor R3 and a collector of the transistor M₅ₙ; the other terminal of the capacitor C3 is grounded; an emitter of the transistor M₅. is grounded; an emitter of the transistor M₆ₚ is connected to one terminal of the capacitor C2, one terminal of the resistor R4 and a collector of the transistor M₆ₙ; the other terminal of the capacitor C2 is grounded; an emitter of the transistor M₆ₙ is grounded; the other terminal of the resistor R2 serves as a first output terminal of the ADB circuit; the other terminal of the resistor R3 serves as a second output terminal of the ADB circuit; and the other terminal of the resistor R4 serves as a third output terminal of the ADB circuit.

Further, the first driver amplifier module includes a transformer Xfrm1 and a driver amplifier DA1; a primary side of the transformer Xfrm1 serves as an input terminal of the first driver amplifier module; a secondary side of the transformer Xfrm1 includes a first terminal connected to a first input terminal of the driver amplifier DA1, a second terminal connected to a second input terminal of the driver amplifier DA1, and a third terminal connected to an output terminal of the ADB circuit; and a first output terminal and a second output terminal of the driver amplifier DA1 are connected to the first balance terminal amplifier module.

Further, the second driver amplifier module includes a transformer Xfrm2 and a driver amplifier DA2; a primary side of the transformer Xfrm2 serves as an input terminal of the second driver amplifier module; a secondary side of the transformer Xfrm2 includes a first terminal connected to a first input terminal of the driver amplifier DA2, a second terminal connected to a second input terminal of the driver amplifier DA2, and a third terminal connected to the output terminal of the ADB circuit; and a first output terminal and a second output terminal of the driver amplifier DA2 are connected to the second balance terminal amplifier module.

Further, the third driver amplifier module includes a transformer Xfrm3 and a driver amplifier DA3; a primary side of the transformer Xfrm3 serves as an input terminal of the third driver amplifier module; a secondary side of the transformer Xfrm3 includes one terminal connected to a first input terminal of the driver amplifier DA3, and the other terminal connected to a second input terminal of the driver amplifier DA3; and a first output terminal and a second output terminal of the driver amplifier DA3 are connected to the variable XCP.

Further, the first balance terminal amplifier module includes a balance terminal amplifier BA1, a transformer Xfmr4, and a transformer Xfmr7; a primary side of the transformer Xfmr4 serves as an input terminal of the first balance terminal amplifier module; a secondary side of the transformer Xfmr4 includes a first terminal connected to a first input terminal of the balance terminal amplifier BA1, a second terminal connected to a second input terminal of the balance terminal amplifier BA1, and a third terminal connected to the output terminal of the ADB circuit; a first output terminal of the balance terminal amplifier BA1 is connected to one terminal of a primary side of the transformer Xfmr7; a second output terminal of the balance terminal amplifier BA1 is connected to the other terminal of the primary side of the transformer Xfmr7; and a secondary side of the transformer Xfmr7 includes one terminal connected to one terminal of a pass-through terminal of the 90-degree differential coupler Q₃, and the other terminal connected to the other terminal of the pass-through terminal of the 90-degree differential coupler Q₃.

Further, the second balance terminal amplifier module includes a balance terminal amplifier BA2, a transformer Xfmr5, and a transformer Xfmr8; a primary side of the transformer Xfmr5 serves as an input terminal of the second balance terminal amplifier module; a secondary side of the transformer Xfmr5 includes a first terminal connected to a first input terminal of the balance terminal amplifier BA2, a second terminal connected to a second input terminal of the balance terminal amplifier BA2, and a third terminal connected to the output terminal of the ADB circuit; a first output terminal of the balance terminal amplifier BA2 is connected to one terminal of a primary side of the transformer Xfmr8; a second output terminal of the balance terminal amplifier BA2 is connected to the other terminal of the primary side of the transformer Xfmr8; and a secondary side of the transformer Xfmr8 includes one terminal connected to one terminal of a coupling terminal of the 90-degree differential coupler Q₃, and the other terminal connected to the other terminal of the coupling terminal of the 90-degree differential coupler Q₃.

Further, the variable XCP includes a transistor M₁, a transistor M₂, and a transistor M₃; a base of the transistor M₁ is connected to the second output terminal of the driver amplifier DA3, a collector of the transistor M₂ and the control terminal amplifier module; a base of the transistor M₂ is connected to the first output terminal of the driver amplifier DA3, a collector of the transistor M₁ and the control terminal amplifier module; an emitter of the transistor M₁ is connected to a collector of the transistor M₃ and an emitter of the transistor M₂; an emitter of the transistor M₃ is grounded; and a base of the transistor M₃ is connected to the output terminal of the ADB circuit.

Further, the control terminal amplifier module includes a control terminal amplifier CA, a transformer Xfmr6, and a transformer Xfmr9; a primary side of the transformer Xfmr6 serves as an input terminal of the control terminal amplifier module; a secondary side of the transformer Xfmr6 includes one terminal connected to a first input terminal of the control terminal amplifier CA, and the other terminal connected to a second input terminal of the control terminal amplifier CA; a first output terminal of the control terminal amplifier CA is connected to one terminal of a primary side of the transformer Xfmr9; a second output terminal of the control terminal amplifier CA is connected to the other terminal of the primary side of the transformer Xfmr9; and a secondary side of the transformer Xfmr9 includes one terminal connected to one terminal of an isolated terminal of the 90-degree differential coupler Q₃, and the other terminal connected to the other terminal of the isolated terminal of the 90-degree differential coupler Q1.

The present disclosure has the following beneficial effects: With the variable XCP structure, the present disclosure makes a load impedance of a common-source amplifier increase with a power, thereby preventing a gain of the common-source amplifier from decreasing with the power. The present disclosure improves a linearity of the amplifier, without affecting an efficiency in a power back-off region.

### BRIEF DESCRIPTION OF THE DRAWINGS

FIG. 1 is a structural view according to the present disclosure;

FIG. 2 is a schematic view of an ADB circuit;

FIG. 3 is a schematic view of an equivalent circuit of a variable XCP;

FIGS. 4A and 4B show a schematic view for improving a linearity with a variable XCP; and

FIG. 5 illustrates a comparison in a linearity and a power added efficiency (PAE) according to whether a variable XCP is used by an LMBA.

### DETAILED DESCRIPTION OF THE EMBODIMENTS

The specific embodiment of the present disclosure will be described below so that those skilled in the art can understand the present disclosure, but it should be clear that the present disclosure is not limited to the scope of the specific embodiment. For those of ordinary skill in the art, as long as various changes fall within the spirit and scope of the present disclosure defined and determined by the appended claims, these changes are apparent, and all inventions and creations using the concept of the present disclosure are protected.

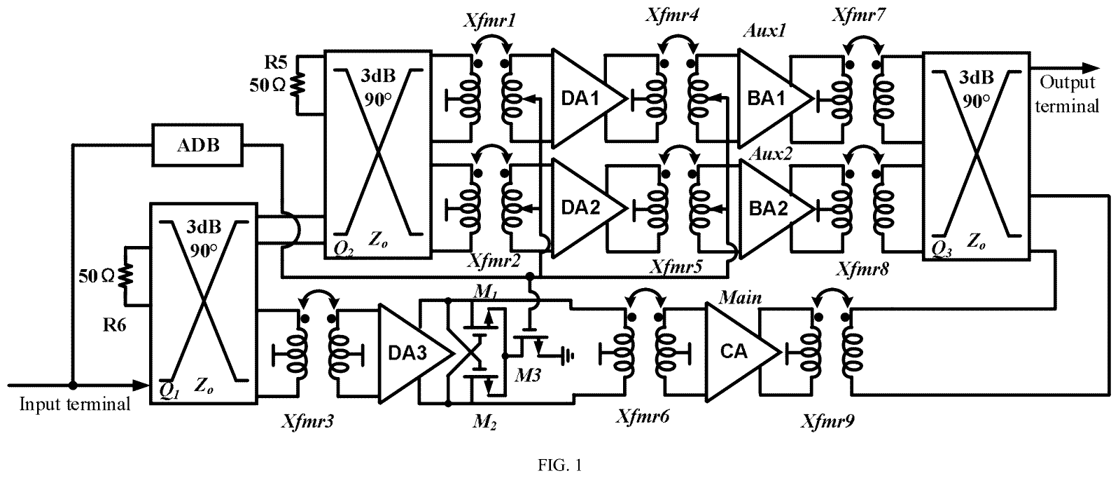

As shown in FIG. 1, an LMBA based on a variable XCP includes an ADB circuit, a first balance terminal amplifier module, a second balance terminal amplifier module, a control terminal amplifier module, a first driver amplifier module, a second driver amplifier module, a third driver amplifier module, a variable XCP, resistor R5, resistor R6, 90-degree differential coupler Q1, 90-degree differential coupler Q2, and 90-degree differential coupler Q3.

An input terminal of the ADB circuit and a third input terminal of the 90-degree differential coupler Q1 each serve as an input terminal of an amplifier. One terminal of an isolated terminal of the 90-degree differential coupler Q1 is connected to the other terminal of the isolated terminal of the 90-degree differential coupler Q1 through the resistor R5. A pass-through terminal of the 90-degree differential coupler Q1 includes one terminal connected to a first input terminal of the 90-degree differential coupler Q2, and the other terminal connected to a second input terminal of the 90-degree differential coupler Q2. One terminal of an isolated terminal of the 90-degree differential coupler Q2 is connected to the other terminal of the isolated terminal of the 90-degree differential coupler Q2 through the resistor R6. A third output terminal of the 90-degree differential coupler Q1 is connected to an input terminal of the third driver amplifier module. An output terminal of the third driver amplifier module is connected to an input terminal of the control terminal amplifier module. A coupling terminal of the 90-degree differential coupler Q2 includes one terminal connected to a first input terminal of the first driver amplifier module, and the other terminal connected to a second input terminal of the first driver amplifier module. A pass-through terminal of the 90-degree differential coupler Q₂ includes one terminal connected to a first input terminal of the second driver amplifier module, and the other terminal connected to a second input terminal of the second driver amplifier module. An output terminal of the first driver amplifier module is connected to an input terminal of the first balance terminal amplifier module. An output terminal of the second driver amplifier module is connected to an input terminal of the second balance terminal amplifier module. A first output terminal and a second output terminal of the first balance terminal amplifier module are respectively connected to one terminal of a pass-through terminal of the 90-degree differential coupler Q₃ and the other terminal of the pass-through terminal of the 90-degree differential coupler Q₃. The second balance terminal amplifier module includes a first output terminal connected to one terminal of a coupling terminal of the 90-degree differential coupler Q₃, and a second output terminal connected to the other terminal of the coupling terminal of the 90-degree differential coupler Q₃. An output terminal of the control terminal amplifier module is connected to an isolated terminal of the 90-degree differential coupler Q₃. An output terminal of the 90-degree differential coupler Q₃ serves as an output terminal of the millimeter-wave LMBA based on the variable XCP.

The first driver amplifier module includes transformer Xfrm1 and driver amplifier DA1. A primary side of the transformer Xfrm1 serves as an input terminal of the first driver amplifier module. A secondary side of the transformer Xfrm1 includes a first terminal connected to a first input terminal of the driver amplifier DA1, a second terminal connected to a second input terminal of the driver amplifier DA1, and a third terminal connected to an output terminal of the ADB circuit. A first output terminal and a second output terminal of the driver amplifier DA1 are connected to the first balance terminal amplifier module.

The second driver amplifier module includes transformer Xfrm2 and driver amplifier DA2. A primary side of the transformer Xfrm2 serves as an input terminal of the second driver amplifier module. A secondary side of the transformer Xfrm2 includes a first terminal connected to a first input terminal of the driver amplifier DA2, a second terminal connected to a second input terminal of the driver amplifier DA2, and a third terminal connected to the output terminal of the ADB circuit. A first output terminal and a second output terminal of the driver amplifier DA2 are connected to the second balance terminal amplifier module.

The third driver amplifier module includes transformer Xfrm3 and driver amplifier DA3. A primary side of the transformer Xfrm3 serves as an input terminal of the third driver amplifier module. A secondary side of the transformer Xfrm3 includes one terminal connected to a first input terminal of the driver amplifier DA3, and the other terminal connected to a second input terminal of the driver amplifier DA3. A first output terminal and a second output terminal of the driver amplifier DA3 are connected to the variable XCP.

The first balance terminal amplifier module includes balance terminal amplifier BA1, transformer Xfmr4, and transformer Xfmr7. A primary side of the transformer Xfmr4 serves as an input terminal of the first balance terminal amplifier module. A secondary side of the transformer Xfmr4 includes a first terminal connected to a first input terminal of the balance terminal amplifier BA1, a second terminal connected to a second input terminal of the balance terminal amplifier BA1, and a third terminal connected to the output terminal of the ADB circuit.

A first output terminal of the balance terminal amplifier BA1 is connected to one terminal of a primary side of the transformer Xfmr7. A second output terminal of the balance terminal amplifier BA1 is connected to the other terminal of the primary side of the transformer Xfmr7. A secondary side of the transformer Xfmr7 includes one terminal connected to one terminal of a pass-through terminal of the 90-degree differential coupler Q₃, and the other terminal connected to the other terminal of the pass-through terminal of the 90-degree differential coupler Q₃.

The second balance terminal amplifier module includes balance terminal amplifier BA2, transformer Xfmr5, and transformer Xfmr8. A primary side of the transformer Xfmr5 serves as an input terminal of the second balance terminal amplifier module. A secondary side of the transformer Xfmr5 includes a first terminal connected to a first input terminal of the balance terminal amplifier BA2, a second terminal connected to a second input terminal of the balance terminal amplifier BA2, and a third terminal connected to the output terminal of the ADB circuit.

A first output terminal of the balance terminal amplifier BA2 is connected to one terminal of a primary side of the transformer Xfmr8. A second output terminal of the balance terminal amplifier BA2 is connected to the other terminal of the primary side of the transformer Xfmr8. A secondary side of the transformer Xfmr8 includes one terminal connected to one terminal of a coupling terminal of the 90-degree differential coupler Q₃, and the other terminal connected to the other terminal of the coupling terminal of the 90-degree differential coupler Q₃.

The variable XCP includes transistor M₁, transistor M₂, and transistor M₃. A base of the transistor M₁ is connected to the second output terminal of the driver amplifier DA3, a collector of the transistor M₂ and the control terminal amplifier module. A base of the transistor M₂ is connected to the first output terminal of the driver amplifier DA3, a collector of the transistor M₁ and the control terminal amplifier module. An emitter of the transistor M₁ is connected to a collector of the transistor M₃ and an emitter of the transistor M₂. An emitter of the transistor M₃ is grounded. A base of the transistor M₃ is connected to the output terminal of the ADB circuit.

The control terminal amplifier module includes control terminal amplifier CA, transformer Xfmr6, and transformer Xfmr9. A primary side of the transformer Xfmr6 serves as an input terminal of the control terminal amplifier module. A secondary side of the transformer Xfmr6 includes one terminal connected to a first input terminal of the control terminal amplifier CA, and the other terminal connected to a second input terminal of the control terminal amplifier CA.

A first output terminal of the control terminal amplifier CA is connected to one terminal of a primary side of the transformer Xfmr9. A second output terminal of the control terminal amplifier CA is connected to the other terminal of the primary side of the transformer Xfmr9. A secondary side of the transformer Xfmr9 includes one terminal connected to one terminal of an isolated terminal of the 90-degree differential coupler Q₃, and the other terminal connected to the other terminal of the isolated terminal of the 90-degree differential coupler Q₁.

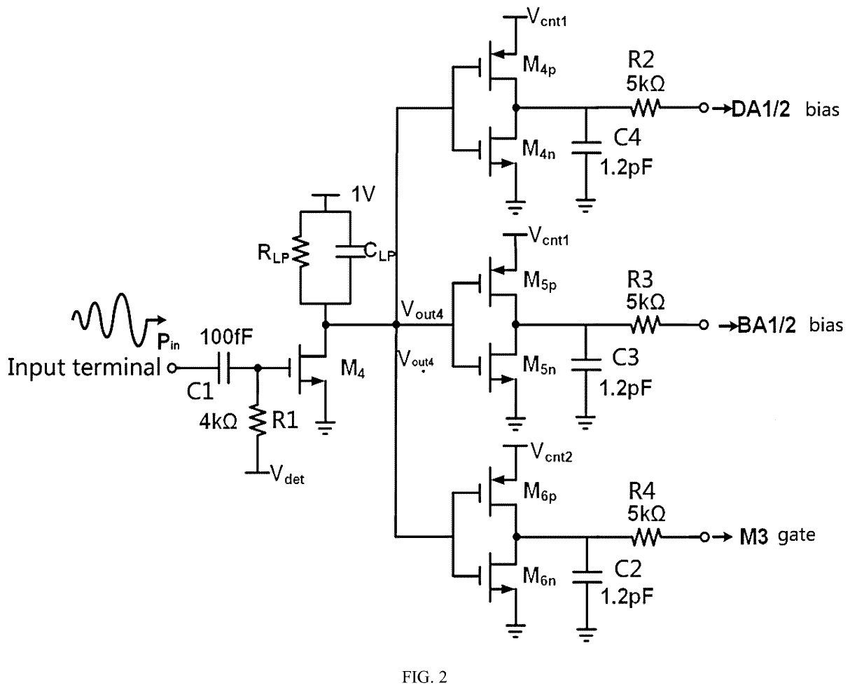

As shown in FIG. 2, the ADB circuit includes transistor M₄ₙ resistor RLP, capacitor CLP, transistor M₄ₙ, transistor M₅ₙ, transistor M₆ₙ, transistor M₄ₚ, transistor M₅ₚ, transistor M6ₚ, resistor R1, resistor R2, capacitor C1, capacitor C2, capacitor C3 and capacitor C4.

The capacitor C1 includes one terminal serving as the input terminal of the ADB circuit, and the other terminal connected to one terminal of the resistor R1 and a base of the transistor M4.

The other terminal of the resistor R1 is connected to a detection voltage. An emitter of the transistor M4 is grounded. A collector of the transistor M4 is connected to one terminal of the resistor R_{LP}, one terminal of the capacitor C_{LP}, a base of the transistor M₄ₙ, a base of the transistor M₅n, a base of the transistor M₆n, a base of the transistor M₄ₚ, a base of the transistor M₅ₚ, and a base of the transistor M₆ₚ. The other terminal of the resistor R_{LP} is connected to a 1V power supply and the other terminal of the capacitor C_{LP}. A collector of the transistor M₄ₚ is connected to a bias voltage V₀nti. A collector of the transistor M₅ₚ is connected to the bias voltage V_{cnt1}. A collector of the transistor M₆ₚ is connected to a bias voltage V_{cnt2}. An emitter of the transistor M₄ₚ is connected to one terminal of the capacitor C4, one terminal of the resistor R2 and a collector of the transistor M₄n. The other terminal of the capacitor C4 is grounded. An emitter of the transistor M₄n is grounded. An emitter of the transistor M₅ₚ is connected to one terminal of the capacitor C3, one terminal of the resistor R3 and a collector of the transistor M₅ₙ.

The other terminal of the capacitor C3 is grounded. An emitter of the transistor M₅ₙ is grounded. An emitter of the transistor M₆ₚ is connected to one terminal of the capacitor C2, one terminal of the resistor R4 and a collector of the transistor M₆ₙ. The other terminal of the capacitor C2 is grounded. An emitter of the transistor M₆ₙ is grounded. The other terminal of the resistor R2 serves as a first output terminal of the ADB circuit. The other terminal of the resistor R3 serves as a second output terminal of the ADB circuit. The other terminal of the resistor R4 serves as a third output terminal of the ADB circuit.

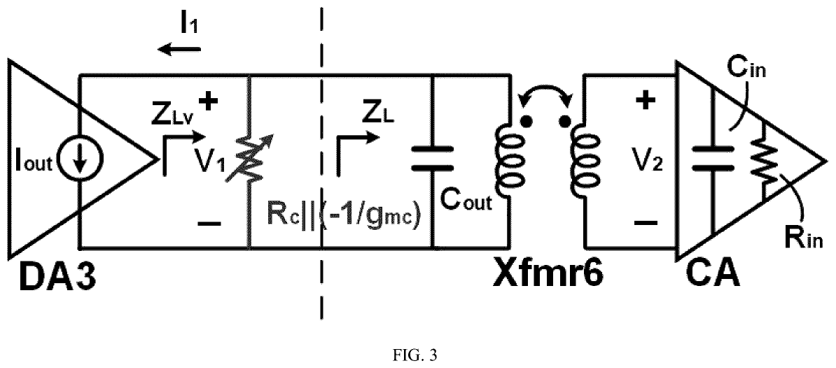

As shown in FIG. 3, the driver amplifier DA3 can be equivalent to a current source Iₒᵤₜ, with a parasitic capacitance Cout. The control terminal amplifier CA is equivalent to an input resistor Rᵢₙ and an input capacitor Cia. The variable XCP is equivalent to a variable resistor.

$${R}_{v} = {R}_{c} ‖ ( - \frac{1}{{g}_{mc}} ) = \frac{{R}_{c}}{1 - {g}_{mc} {R}_{c}}$$

After the variable XCP is provided between DA3 and Xfmr6, a load impedance of the DA3 is changed from Z_{L} to Z_{Lv}.

$${Z}_{L} \to {Z}_{Lv} = {R}_{ν} ‖ {Z}_{L} = \frac{{Z}_{L} {R}_{c}}{{Z}_{L} - {R}_{c} - {g}_{mc} {Z}_{L} {R}_{c}}$$

The DA3 linearly amplifies its input voltage Vᵢₙ, with a transconductance Gm, thereby obtaining:

$${V}_{1} = {I}_{out} \times {Z}_{{L}_{ν}} = {G}_{m} {V}_{in} {Z}_{{L}_{v}}$$

$${G}_{DA 3} = \frac{{V}_{1}}{{V}_{in}} = {G}_{m} {Z}_{{L}_{v}} .$$

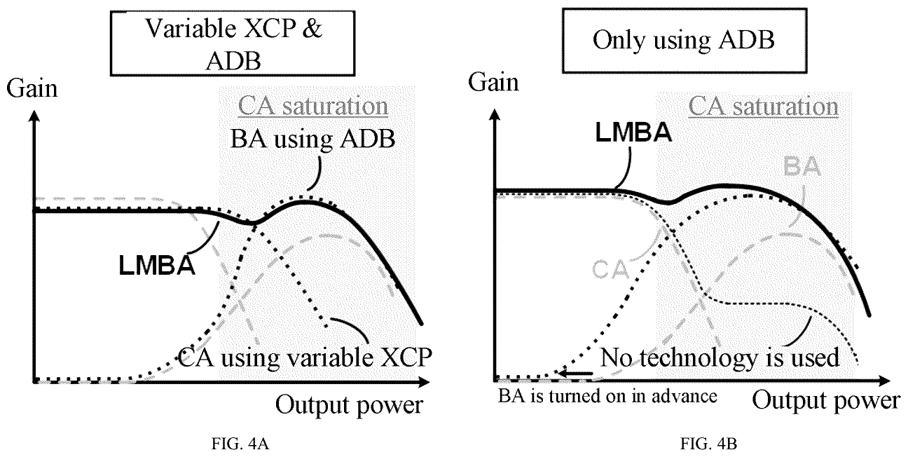

As shown in FIGS. 4A and 4B, the variable XCP structure improves a linearity of the control terminal amplifier CA in a saturation region. The BA1/2 using the ADB has a higher gain in the saturation region. With the variable XCP structure, the ADB voltage threshold is high, such that the BA1/2 is not turned on in advance to affect an efficiency in the power back-off region. FIG. 4B illustrates a solution in which an overall linearity is improved only with an ADB. Due to a large power back-off range, in order to compensate a gain of the CA in saturation and serious compression, the ADB voltage threshold is low to improve the gain of the turn-on BA. Consequently, the BA1/2 is turned on in advance to affect the power back-off efficiency.

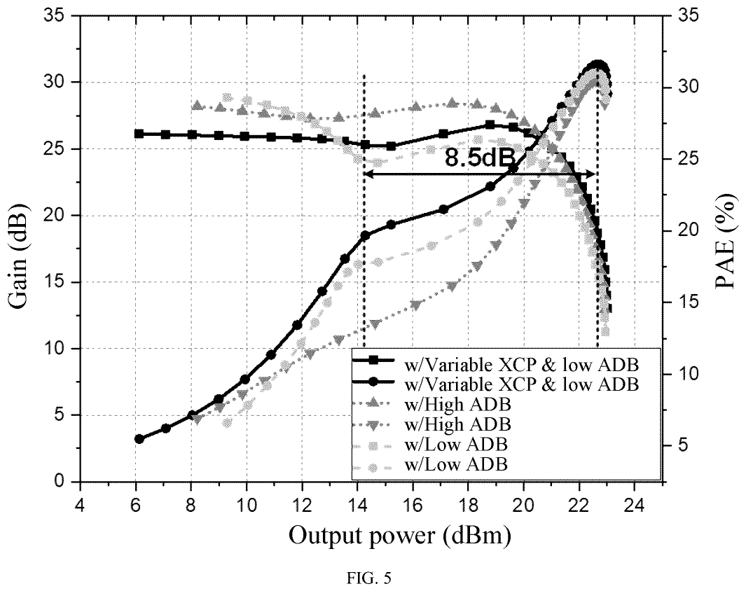

As shown in FIG. 5, the solid line refers to a simulation test result when the variable XCP structure is used in the present disclosure, the dash line refers to a simulation test result when the variable XCP structure is not used under same circuit parameters, and a dotted line refers to a simulation test result when only the ADB is used to improve the linearity. In combination with the variable XCP structure and the ADB (the solid line), the overall linearity of the amplifier is improved. When the variable XCP structure is turned off, and the same ADB voltage threshold is used (the dash line), the linearity of the amplifier is affected, and the power back-off efficiency is reduced slightly. When the variable XCP structure is turned off, and the ADB voltage threshold is improved (the dotted line), the linearity of the amplifier is improved, but the power back-off efficiency is affected seriously. In combination with the variable XCP structure and the ADB, the BA1/2 is not turned on in advance for the high ADB voltage threshold to affect the power back-off efficiency.

In an embodiment of the present disclosure, the present disclosure has a higher power back-off efficiency at 28 GHz and 8.5 dB. Compared with the solution only using the ADB, the present disclosure based on the variable XCP structure improves a linearity of the millimeter-wave LMBA, while achieving a higher back-off efficiency. Through the ADB, a direct-current (DC) voltage increasing with an increase of an input signal power is output to control a gate of the transistor M3. With an increase of gₘₑ, Z_{Lv} increases. With the increase of the input signal power, Gₘ decreases. Through opposite variation tendencies, V₁ is relatively stable. Therefore, the tendency in which the gain G_{DA3} of the DA3 decreases with the increase of the input power is alleviated.

With the variable XCP structure, the present disclosure makes a load impedance of a common-source amplifier increase with a power, thereby preventing a gain of the common-source amplifier from decreasing with the power. The present disclosure improves a linearity of the amplifier, without affecting an efficiency in a power back-off region.

What is claimed is:

1. A load-modulated balanced amplifier (LMBA) based on a variable cross-coupled pair (XCP), comprising an adaptive bias (ADB) circuit, a first balance terminal amplifier module, a second balance terminal amplifier module, a control terminal amplifier module, a first driver amplifier module, a second driver amplifier module, a third driver amplifier module, a variable XCP, a resistor R5, a resistor R6, a 90-degree differential coupler Q1, a 90-degree differential coupler Q2, and a 90-degree differential coupler Q3, wherein
an input terminal of the ADB circuit and a third input terminal of the 90-degree differential coupler Q1 each serve as an input terminal of an amplifier;
one terminal of an isolated terminal of the 90-degree differential coupler Q1 is connected to the other terminal of the isolated terminal of the 90-degree differential coupler Q1 through the resistor R5;
a pass-through terminal of the 90-degree differential coupler Q1 comprises one terminal connected to a first input terminal of the 90-degree differential coupler Q2, and the other terminal connected to a second input terminal of the 90-degree differential coupler Q2;
one terminal of an isolated terminal of the 90-degree differential coupler Q2 is connected to the other terminal of the isolated terminal of the 90-degree differential coupler Q2 through the resistor R6;
a third output terminal of the 90-degree differential coupler Q1 is connected to an input terminal of the third driver amplifier module;
an output terminal of the third driver amplifier module is connected to an input terminal of the control terminal amplifier module;
a coupling terminal of the 90-degree differential coupler Q₂ comprises one terminal connected to a first input terminal of the first driver amplifier module, and the other terminal connected to a second input terminal of the first driver amplifier module;
a pass-through terminal of the 90-degree differential coupler Q₂ comprises one terminal connected to a first input terminal of the second driver amplifier module, and the other terminal connected to a second input terminal of the second driver amplifier module;
an output terminal of the first driver amplifier module is connected to an input terminal of the first balance terminal amplifier module;
an output terminal of the second driver amplifier module is connected to an input terminal of the second balance terminal amplifier module;
a first output terminal and a second output terminal of the first balance terminal amplifier module are respectively connected to one terminal of a pass-through terminal of the 90-degree differential coupler Q₃ and the other terminal of the pass-through terminal of the 90-degree differential coupler Q₃;
the second balance terminal amplifier module comprises a first output terminal connected to one terminal of a coupling terminal of the 90-degree differential coupler Q₃, and a second output terminal connected to the other terminal of the coupling terminal of the 90-degree differential coupler Q₃;
an output terminal of the control terminal amplifier module is connected to an isolated terminal of the 90-degree differential coupler Q₃; and an output terminal of the 90-degree differential coupler Q₃ serves as an output terminal of the millimeter-wave LMBA based on the variable XCP.

2. The LMBA based on the variable XCP according to claim 1,
wherein the ADB circuit comprises a transistor M₄ₙ a resistor R_{LP}, a capacitor C_{LP}, a transistor M₄ₙ, a transistor M₅ₙ, a transistor M₆ₙ, a transistor M₄ₚ, a transistor M₅ₚ, a transistor M₆ₚ, a resistor R1, a resistor R2, a capacitor C1, a capacitor C2, a capacitor C3 and a capacitor C4; and
the capacitor C1 comprises one terminal serving as the input terminal of the ADB circuit, and the other terminal connected to one terminal of the resistor R1 and a base of the transistor M₄;
the other terminal of the resistor R1 is connected to a detection voltage;
an emitter of the transistor M₄ is grounded;
a collector of the transistor M₄ is connected to one terminal of the resistor R_{LP}, one terminal of the capacitor C_{LP}, a base of the transistor M₄ₙ, a base of the transistor M₅ₙ, a base of the transistor M₆ₙ, a base of the transistor M₄ₚ, a base of the transistor M₅ₚ, and a base of the transistor M₆ₚ;
the other terminal of the resistor R_{LP} is connected to a 1V power supply and the other terminal of the capacitor C_{LP};
a collector of the transistor M₄ₚ is connected to a bias voltage V_{cnt1};
a collector of the transistor M₅ₚ is connected to the bias voltage V_{cnt1};
a collector of the transistor M₆ₚ is connected to a bias voltage V_{cnt2};
an emitter of the transistor M₄ₚ is connected to one terminal of the capacitor C4, one terminal of the resistor R2 and a collector of the transistor M₄ₙ;
the other terminal of the capacitor C4 is grounded;
an emitter of the transistor M₄n is grounded;
an emitter of the transistor M₅ₚ is connected to one terminal of the capacitor C3, one terminal of the resistor R3 and a collector of the transistor M₅ₙ;
the other terminal of the capacitor C3 is grounded;
an emitter of the transistor M₅ₙ is grounded;
an emitter of the transistor M₆ₚ is connected to one terminal of the capacitor C2, one terminal of the resistor R4 and a collector of the transistor M₆ₙ;
the other terminal of the capacitor C2 is grounded;
an emitter of the transistor M₆ₙ is grounded;
the other terminal of the resistor R2 serves as a first output terminal of the ADB circuit;
the other terminal of the resistor R3 serves as a second output terminal of the ADB circuit; and
the other terminal of the resistor R4 serves as a third output terminal of the ADB circuit.

3. The LMBA based on the variable XCP according to claim 1, wherein the first driver amplifier module comprises a transformer Xfrm1 and a driver amplifier DA1;
a primary side of the transformer Xfrm1 serves as an input terminal of the first driver amplifier module;
a secondary side of the transformer Xfrm1 comprises a first terminal connected to a first input terminal of the driver amplifier DA1, a second terminal connected to a second input terminal of the driver amplifier DA1, and a third terminal connected to an output terminal of the ADB circuit; and
a first output terminal and a second output terminal of the driver amplifier DA1 are connected to the first balance terminal amplifier module.

4. The LMBA based on the variable XCP according to claim 3, wherein the second driver amplifier module comprises a transformer Xfrm2 and a driver amplifier DA2; a primary side of the transformer Xfrm2 serves as an input terminal of the second driver amplifier module; a secondary side of the transformer Xfrm2 comprises a first terminal connected to a first input terminal of the driver amplifier DA2, a second terminal connected to a second input terminal of the driver amplifier DA2, and a third terminal connected to the output terminal of the ADB circuit; and a first output terminal and a second output terminal of the driver amplifier DA2 are connected to the second balance terminal amplifier module.

5. The LMBA based on the variable XCP according to claim 3, wherein the third driver amplifier module comprises a transformer Xfrm3 and a driver amplifier DA3; a primary side of the transformer Xfrm3 serves as an input terminal of the third driver amplifier module; a secondary side of the transformer Xfrm3 comprises one terminal connected to a first input terminal of the driver amplifier DA3, and the other terminal connected to a second input terminal of the driver amplifier DA3; and a first output terminal and a second output terminal of the driver amplifier DA3 are connected to the variable XCP.

6. The LMBA based on the variable XCP according to claim 3, wherein the first balance terminal amplifier module comprises a balance terminal amplifier BA1, a transformer Xfmr4, and a transformer Xfmr7;
a primary side of the transformer Xfmr4 serves as an input terminal of the first balance terminal amplifier module;
a secondary side of the transformer Xfmr4 comprises a first terminal connected to a first input terminal of the balance terminal amplifier BA1, a second terminal connected to a second input terminal of the balance terminal amplifier BA1, and a third terminal connected to the output terminal of the ADB circuit;
a first output terminal of the balance terminal amplifier BA1 is connected to one terminal of a primary side of the transformer Xfmr7;
a second output terminal of the balance terminal amplifier BA1 is connected to the other terminal of the primary side of the transformer Xfmr7; and
a secondary side of the transformer Xfmr7 comprises one terminal connected to one terminal of a pass-through terminal of the 90-degree differential coupler Q₃, and the other terminal connected to the other terminal of the pass-through terminal of the 90-degree differential coupler Q₃.

7. The LMBA based on the variable XCP according to claim 3, wherein the second balance terminal amplifier module comprises a balance terminal amplifier BA2, a transformer Xfmr5, and a transformer Xfmr8;
a primary side of the transformer Xfmr5 serves as an input terminal of the second balance terminal amplifier module;
a secondary side of the transformer Xfmr5 comprises a first terminal connected to a first input terminal of the balance terminal amplifier BA2, a second terminal connected to a second input terminal of the balance terminal amplifier BA2, and a third terminal connected to the output terminal of the ADB circuit;
a first output terminal of the balance terminal amplifier BA2 is connected to one terminal of a primary side of the transformer Xfmr8;
a second output terminal of the balance terminal amplifier BA2 is connected to the other terminal of the primary side of the transformer Xfmr8; and
a secondary side of the transformer Xfmr8 comprises one terminal connected to one terminal of a coupling terminal of the 90-degree differential coupler Q₃, and the other terminal connected to the other terminal of the coupling terminal of the 90-degree differential coupler Q₃.

8. The LMBA based on the variable XCP according to claim 5, wherein the variable XCP comprises a transistor M₁, a transistor M₂, and a transistor M₃;
a base of the transistor M₁ is connected to the second output terminal of the driver amplifier DA3, a collector of the transistor M₂ and the control terminal amplifier module;
a base of the transistor M₂ is connected to the first output terminal of the driver amplifier DA3, a collector of the transistor M₁ and the control terminal amplifier module;
an emitter of the transistor M₁ is connected to a collector of the transistor M₃ and an emitter of the transistor M₂;
an emitter of the transistor M₃ is grounded; and
a base of the transistor M₃ is connected to the output terminal of the ADB circuit.

9. The LMBA based on the variable XCP according to claim 8, wherein the control terminal amplifier module comprises a control terminal amplifier CA, a transformer Xfmr6, and a transformer Xfmr9;
a primary side of the transformer Xfmr6 serves as an input terminal of the control terminal amplifier module;
a secondary side of the transformer Xfmr6 comprises one terminal connected to a first input terminal of the control terminal amplifier CA, and the other terminal connected to a second input terminal of the control terminal amplifier CA;
a first output terminal of the control terminal amplifier CA is connected to one terminal of a primary side of the transformer Xfmr9;
a second output terminal of the control terminal amplifier CA is connected to the other terminal of the primary side of the transformer Xfmr9; and
a secondary side of the transformer Xfmr9 comprises one terminal connected to one terminal of the isolated terminal of the 90-degree differential coupler Q₃, and the other terminal connected to the other terminal of the isolated terminal of the 90-degree differential coupler Q₁.
